(19) United States
(12) Patent Application Publication
(10) Pub. No.: US 2025/0349754 A1
(43) Pub. Date: Nov. 13, 2025

(54) SYSTEMS AND METHODS FOR PREVENTING FAULT INJECTION ATTACKS THROUGH A BACK SIDE OF A DIE

(71) Applicant: Advanced Micro Devices, Inc., Santa Clara, CA (US)

(72) Inventors: Mohit Arora, Austin, TX (US); Deepak Vasant Kulkarni, Austin, TX (US); Richard E. George, Santa Clara, CA (US); Terry Eugene Richardson, Austin, TX (US)

(73) Assignee: Advanced Micro Devices, Inc., Santa Clara, CA (US)

(21) Appl. No.: 18/316,973

(22) Filed: May 12, 2023

(51) Int. Cl. H01L 23/00; H01L 23/36; H01L 25/065

(52) U.S. Cl. CPC H01L 23/573; H01L 23/36; H01L 24/32; H01L 24/83; H01L 25/0657; H01L 2224/32225; H01L 2224/8389

(57) ABSTRACT

A computer-implemented method for preventing fault injection attacks through a back side of a die can include providing a stacked silicon die. The method can also include providing an oxide layer on a back side of the stacked silicon die. The method can further include permanently attaching a selective glass carrier to the oxide layer in a position that restricts voltage glitches from reaching a power subsystem of the stacked silicon die. Various other methods, systems, and computer-readable media are also disclosed.

### BACKGROUND

Challenges arise in protecting against fault injection attacks through a back side of an integrated die through logical and/or circuit level techniques. Example fault injection attacks include body biasing injection (BBI) attacks, electromagnetic fault injection (EMFI) attacks, and laser fault injection (LFI) attacks. These attacks are considered low-cost attacks that inject voltage pulses that couple with chip structure.

Flip chip packaging exposes the back side of the die, making these types of packages particularly vulnerable to fault injection attacks. For example, chips of flip chip packages can include all the protection/security on a front side of the die while completely exposing the back side of the die. For example, all that is required for BBI attacks is to remove the heat sink, a semi-invasive measure, mounted on the package and, in some cases, thin a silicon carrier. With this meager preparation, a probe can inject a voltage glitch in a power structure of the die by applying bias to the bulk silicon. There exists no current defense against such attacks.

### BRIEF DESCRIPTION OF THE DRAWINGS

The accompanying drawings illustrate a number of example embodiments and are a part of the specification. Together with the following description, these drawings demonstrate and explain various principles of the present disclosure.

FIG. 1 is a flow diagram of an example method for preventing fault injection attacks through a back side of a die.

FIG. 2 is a block diagram illustrating an example of a fault injection attack.

FIG. 3 is a block diagram illustrating example systems on chip.

FIG. 4 is a block diagram illustrating example wafer level fanout packages.

FIG. 5 is a block diagram illustrating example selective glass carriers.

FIG. 6 is a block diagram illustrating example 3D stacked integrated circuit package.

FIG. 7 is a block diagram illustrating example 2.5D stacked integrated circuit packages.

Throughout the drawings, identical reference characters and descriptions indicate similar, but not necessarily identical, elements. While the example embodiments described herein are susceptible to various modifications and alternative forms, specific embodiments have been shown by way of example in the drawings and will be described in detail herein. However, the example embodiments described herein are not intended to be limited to the particular forms disclosed. Rather, the present disclosure covers all modifications, equivalents, and alternatives falling within the scope of the appended claims.

### DETAILED DESCRIPTION OF EXAMPLE IMPLEMENTATIONS

The present disclosure is generally directed to systems and methods for preventing fault injection attacks through a back side of a die. For example, by adding an oxide layer (e.g., thickness 1-2 um) on a back side of a stacked silicon die (e.g., between transistors and bulk silicon), voltage glitches can be restricted from reaching a power subsystem of a stacked silicon die package. The oxide layer can function as an electrical insulator that acts as a barrier to injected voltage pulses, thus preventing a low-cost fault injection attack on the package and one or more security assets (e.g., on a root of trust (ROT) and/or die to die interconnect) of the stacked silicon die. In some implementations, the oxide layer can permanently attach a selective glass carrier on the back side of the package. The glass carrier can also function as an electrical insulator that acts as a barrier to injected voltage pulses, thus further preventing the low-cost fault injection attacks on the package. In some of these implementations, the oxide layer can permanently attach one or more the selective glass carriers on the back side of the package in one or more locations of one or more security assets. The rest of the backside of the stacked silicon die can be exposed to allow mounting of a heat sink to address thermal issues by providing a thermal path while the oxide layer and glass carrier provide electrical insulation for the one or more security assets. Benefits include a low cost way to prevent fault injection attacks through a back side of a die for performance applications that experience thermal issues.

In one example, an integrated circuit can include a stacked silicon die, an oxide layer provided on a back side of the stacked silicon die, and a selective glass carrier permanently attached to the oxide layer in a position that restricts voltage glitches from reaching a power subsystem of the stacked silicon die.

Another example can be the previously described example integrated circuit, wherein the oxide layer permanently attaches the selective glass carrier on the back side of the stacked silicon die in a location of a security asset of the stacked silicon die.

Another example can be any of the previously described example integrated circuits, wherein the security asset corresponds to a root of trust of the stacked silicon die.

Another example can be any of the previously described example integrated circuits, wherein the security asset corresponds to a die to die interconnect of the stacked silicon die.

Another example can be any of the previously described example integrated circuits, wherein the selective glass carrier extends beyond the location of the security asset to an extent sufficient to reduce a success rate of fault injection attacks from a side of the security asset.

Another example can be any of the previously described example integrated circuits, wherein the selective glass carrier is not positioned in an area of the stacked silicon die that does not contain a security asset.

In one example, an integrated circuit package can include an integrated circuit that includes a stacked silicon die, an oxide layer on a back side of the stacked silicon die, and a selective glass carrier permanently attached to the oxide layer in a position that restricts voltage glitches from reaching a power subsystem of the stacked silicon die, a bonding silicon layer provided on the oxide layer in an area of the stacked silicon die in which the selective glass carrier is not permanently attached, a silicon carrier attached to the selective glass carrier and the bonding silicon layer, and a substrate attached to a front side of the stacked silicon die.

Another example can be the previously described integrated circuit package, further comprising a heat sink attached to the silicon carrier.

Another example can be any of the previously described integrated circuit packages, further including an additional oxide layer attaching the silicon carrier to the selective glass carrier and the bonding silicon layer.

Another example can be any of the previously described integrated circuit packages, wherein the oxide layer permanently attaches the selective glass carrier on the back side of the stacked silicon die in a location of a security asset of the stacked silicon die.

Another example can be any of the previously described integrated circuit packages, wherein the security asset corresponds to a root of trust of the stacked silicon die.

Another example can be any of the previously described integrated circuit packages, wherein the security asset corresponds to a die to die interconnect of the stacked silicon die.

Another example can be any of the previously described integrated circuit packages, wherein the selective glass carrier extends beyond the location of the security asset to an extent sufficient to reduce a success rate of fault injection attacks from a side of the security asset.

Another example can be any of the previously described integrated circuit packages, wherein the selective glass carrier is not positioned in an area of the stacked silicon die that does not contain a security asset.

Another example can be any of the previously described integrated circuit packages, wherein the stacked silicon die includes two or more 3D stacked silicon dies.

Another example can be any of the previously described integrated circuit packages, wherein the stacked silicon die includes multiple silicon dies stacked on an interposer.

In one example, a method includes providing a stacked silicon die, providing an oxide layer on a back side of the stacked silicon die, and permanently attaching a selective glass carrier to the oxide layer in a position that restricts voltage glitches from reaching a power subsystem of the stacked silicon die.

Another example can be the previously described example method, wherein the oxide layer permanently attaches the selective glass carrier on the back side of the stacked silicon die in a location of a security asset of the stacked silicon die.

Another example can be any of the previously described example methods, wherein the security asset corresponds to at least one of a root of trust of the stacked silicon die or a die to die interconnect of the stacked silicon die.

Another example can be any of the previously described example methods, wherein the selective glass carrier extends beyond the location of the security asset to an extent sufficient to reduce a success rate of fault injection attacks from a side of the security asset.

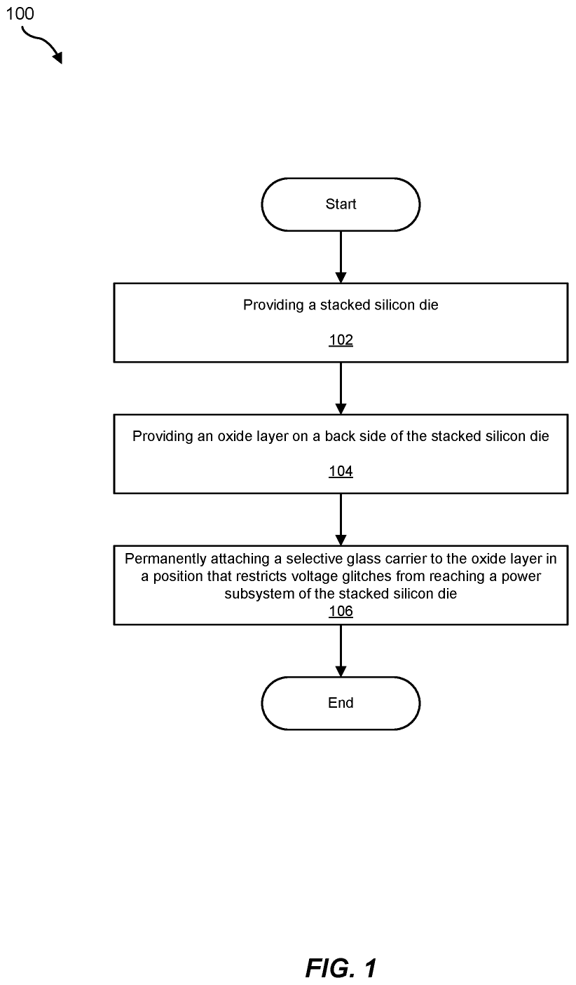

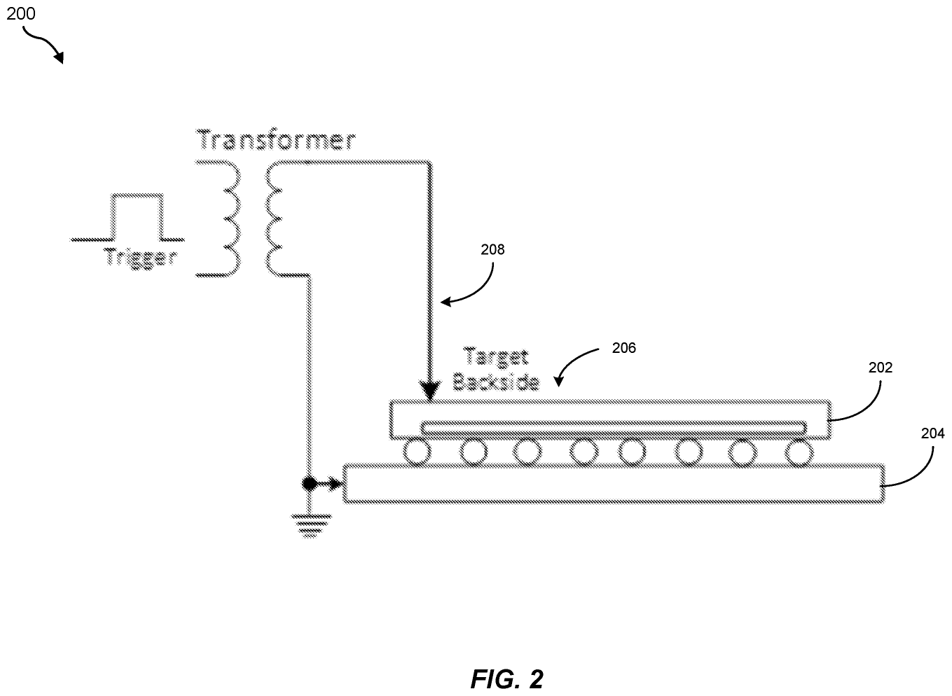

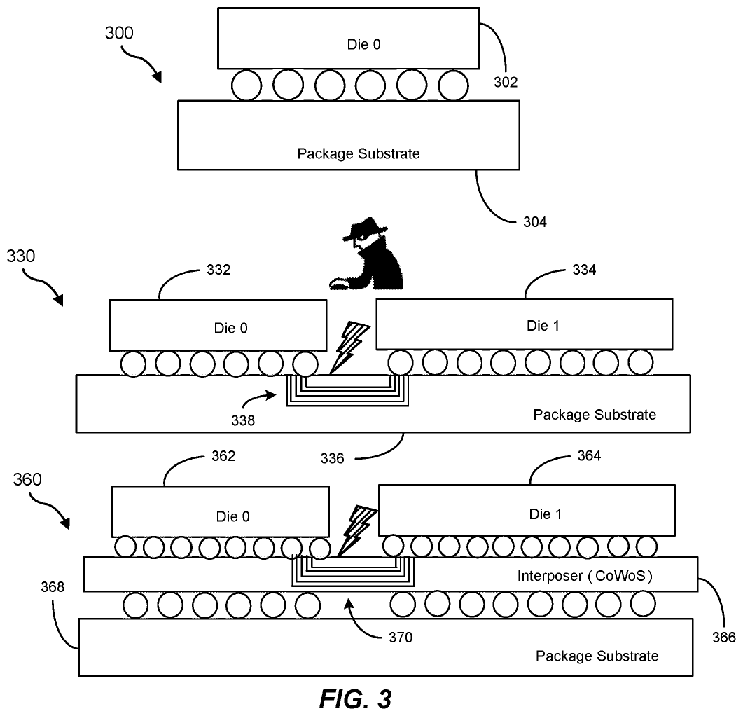

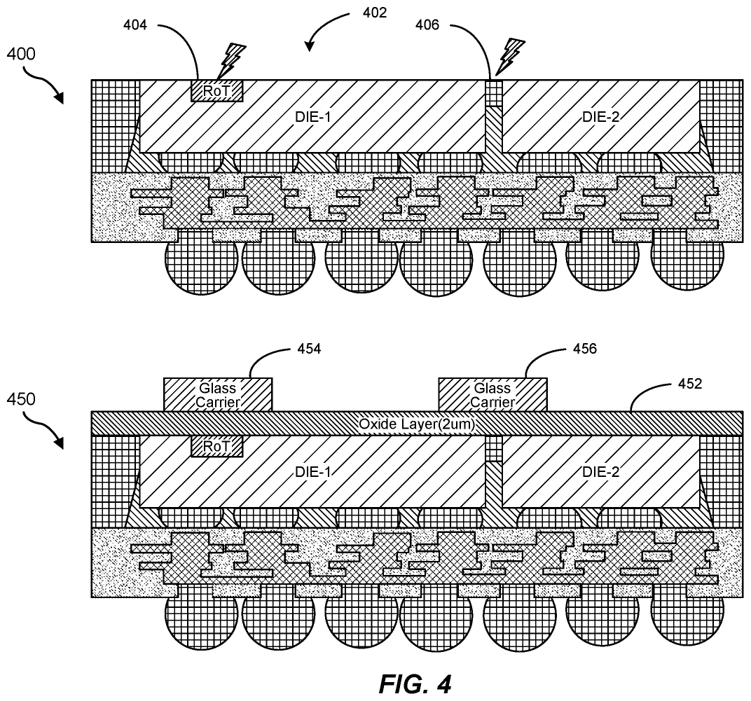

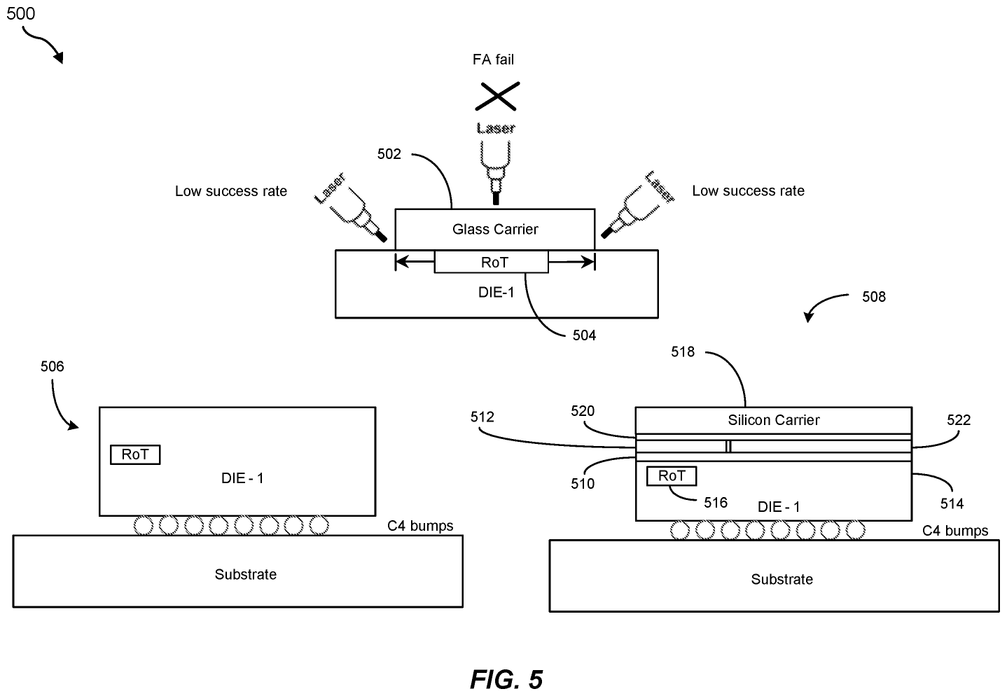

The following will provide, with reference to FIG. 1, detailed descriptions of an example method for preventing fault injection attacks through a back side of a die. In addition, detailed descriptions of an example fault injection attack will be provided in connection with FIG. 2. Also, detailed descriptions of example systems on chip will be provided in connection with FIG. 3. Further, detailed descriptions of example wafer level fanout packages will be provided in connection with FIG. 4. Finally, detailed descriptions of example selective glass carriers will be provided in connection with FIG. 5.

FIG. 1 is a flow diagram of an example method 100 for preventing fault injection attacks through a back side of a die. The steps shown in FIG. 1 can be performed by any suitable computer-executable code and/or computing system. In one example, each of the steps shown in FIG. 1 can represent an algorithm whose structure includes and/or is represented by multiple sub-steps, examples of which will be provided in greater detail below.

As illustrated in FIG. 1, step 102 can include providing a die. For example, step 102 can include providing a stacked silicon die.

The term “stacked silicon die,” as used herein, can generally refer to a process of mounting multiple chips on top of each other within a single semiconductor package. Die stacking, which is also known as “chip stacking,” significantly increases the amount of silicon chip area that can be housed within a single package of a given footprint, conserving precious real estate on the printed circuit board and simplifying the board assembly process. Aside from space savings, die stacking also results in better electrical performance of the device, since the shorter routing of interconnections between circuits results in faster signal propagation and reduction in noise and cross-talk.

The systems described herein can perform step 102 in a variety of ways. In one example, step 102 can include receiving a prefabricated stacked silicon die and placing it on a workstation (e.g., in an ultra-clean environment). Alternatively, step 102 can include manufacturing the stacked silicon die (e.g., using a wafer on wafer and/or chip on wafer process). In some of these implementations, manufacturing the stacked silicon die can include placing a substrate and/or carrier on a workstation (e.g., in an ultra-clean environment) and forming a silicon wafer on the carrier and/or substrate. In some of these implementations, multiple wafers can be formed one atop another. In some implementations, one or more of the wafers can be thinned to reveal vias and/or hybrid bonds prior to formation of a next wafer. In some of these implementations, one or more of the wafers can include transistors configured as one or more microprocessors that constitute one or more security assets (e.g., a root of trust of the stacked silicon die). In some implementations, a substrate (e.g., bulk silicon), can be formed atop a carrier and/or oxide layer. In some implementations, a carrier and/or substrate can be removed following formation of the wafers. In other implementations, a substrate and/or carrier can be permanently attached. In some implementations, the wafers can be diced into chips and mounted on an interposer, carrier, and/or substrate using bumps (e.g., C4 bumps), hybrid bonding, direct bonding, etc. Alternatively or additionally, a substrate (e.g., bulk silicon) including all or part of a power subsystem can form part of the stacked silicon die.

The term “root of trust,” as used herein, can generally refer to a logic block that resides in a silicon die that maintains the trust. For example, and without limitation, a root of trust can maintain a trust using one or more encryption schemes, digital signatures, and/or secret keys. In use, a root of trust (ROT) can be implemented as a source that can always be trusted within a cryptographic system. Because cryptographic security is dependent on keys to encrypt and decrypt data and perform functions such as generating digital signatures and verifying signatures, ROT schemes generally include a hardened hardware module. In this context, a hardware root of trust can be the foundation on which all secure operations of a computing system depend. It can contain the keys used for cryptographic functions and enable a secure boot process. It is inherently trusted, and therefore must be secure by design. The most secure implementation of a root of trust is in hardware making it immune from malware attacks. As such, it can be a stand-alone security module or implemented as security module within a processor or system on chip (SoC).

Step 104 can include providing an oxide layer. For example, step 104 can include providing an oxide layer on a back side of the stacked silicon die.

The term “oxide layer,” as used herein, can generally refer to a thin layer or coating of an oxide that provides electrical insulation, such as silicon dioxide. For example, oxide layer can generally refer to magnesium oxide (MgO), aluminum oxide (Al₂O₃), silicon dioxide (SiO₂), a transition metal oxide (e.g., titanium dioxide (TiO₂), strontium titanate (SrTiO₃)), any other oxide that is an electrical insulator, and combinations thereof.

The systems described herein can perform step 104 in a variety of ways. In one example, the oxide layer can be deposited on the back side of the stacked silicon die by thermal oxidation, wet anodization, chemical vapor deposition, and/or plasma anodization or oxidation. In some examples, the oxide layer can include silicon dioxide (SiO₂). In other examples, the oxide layer can include magnesium oxide (MgO), aluminum oxide (Al₂O₃), silicon dioxide (SiO₂), a transition metal oxide (e.g., titanium dioxide (TiO₂), strontium titanate (SrTiO₃)), any other oxide that is an electrical insulator, and combinations thereof. In some examples, the oxide layer can have a thickness in a range of one to two micrometers. This thickness can be tuned during deposition and/or by thinning thereof to modify the breakdown voltage of the oxide layer.

Step 106 can include attaching a glass carrier. For example, step 106 can include permanently attaching a selective glass carrier to the oxide layer in a position that restricts voltage glitches from reaching a power subsystem of the stacked silicon die.

The term “carrier,” as used herein, can generally refer to a surface-mount technology package for integrated circuits. For example, and without limitation, carriers can be glass carriers, quartz carriers, or silicon carriers. Bottom carriers can be employed as a base platform in a wafer on wafer stacking process to provide structural support during wafer chip manufacture. Such carriers can often be removed before, during, or after packaging the integrated circuit. Top carriers can be added on top of an integrated circuit for protection and structural support. Top carriers can also be removed before, during, or after packaging of the integrated circuit.

The term “glass carrier,” as used herein, can generally refer to precision planes (e.g., disks) of thin glass, such as borosilicate glass. For example, and without limitation, glass carriers can be created by selecting an appropriate high-quality glass material and then carefully cutting and shaping it. Numerous finishing processes can be performed to perfect the carrier wafer's flatness before it undergoes rigorous quality inspection processes using precision laser measuring equipment. Although glass carriers are typically removed from semiconductor devices, cleaned, and reused, the systems and methods of the present disclosure can permanently attach a glass carrier to a backside of an integrated circuit as part of a packaging process. According to the disclosed systems and methods, any glass carrier capable of functioning as an electrical insulator can be used. A glass carrier can, thus, be distinguished from a silicon carrier because a silicon carrier is typically composed of silicon dioxide, which is not functionally effective as an electrical insulator but provides significantly greater thermal conductivity. In this context, a “selective glass carrier” can be a glass carrier that does not cover an entirety of a backside of the stacked silicon die and is selectively positioned to protect one or more security assets of the stacked silicon die from fault injection attacks.

The term “voltage glitch,” as used herein, can generally refer to violent modification of a supply voltage of a circuit for a very short time, so that it ends up in an inappropriate state. For example, and without limitation, voltage glitch can refer to active side channel attacks that modify the execution-flow of a device by creating disturbances on the power supply line, thus skipping security checks or generating side-channels that gradually leak sensitive data, including the firmware code. Alternatively or additionally, voltage glitch can refer, without limitation, to attacks that involve causing a hardware fault through manipulating the environmental variables in a system. Such a hardware fault can be temporary or persistent across power cycles (e.g., permanent).

The term “power subsystem,” as used herein, can generally refer to components that deliver power to attached instruments and sensors. For example, and without limitation, a power subsystem can begin with power feed equipment and end with final output voltage converter and filters. Depending on implementation, either constant current or constant voltage power feeding may be used.

The systems described herein can perform step 106 in a variety of ways. In one example, the oxide layer can be used to permanently attach the selective glass carrier on the back side of the stacked silicon die in a location of a security asset of the stacked silicon die. In some examples, the security asset can correspond to a root of trust of the stacked silicon die and/or a die to die interconnect of the stacked silicon die. In some examples, positioning of the selective glass carrier can avoid covering an area of the stacked silicon die that does not contain a security asset. In some examples, the selective glass carrier can extend beyond the location of the security asset to an extent sufficient to reduce a success rate of fault injection attacks from a side of the security asset. In additional examples, characteristics of the selective glass carrier (e.g., carrier thickness, carrier width, carrier location) can be tuned for different integrated circuits to provide suitable electrical insulation for a security asset and thermal conductivity for other portions of an area of the backside of the stacked silicon die. In some examples, step 106 can further include providing a bonding silicon layer on the oxide layer in an area of the stacked silicon die in which the selective glass carrier is not permanently attached and attaching a silicon carrier to the selective glass carrier and the bonding silicon layer. In some of these examples, step 106 can further include attaching a heat sink to the silicon carrier using an additional oxide layer. In this way, the glass carrier and oxide layer can provide electrical insulation that protects one or more security assets (e.g., root of trust and/or die to die interconnect) of the stacked silicon die from fault injection attacks while also providing sufficient thermal conductivity for applications that require a heat sink.

FIG. 2 illustrates an example 200 of a body biasing injection attack. For example, a flip chip package can have a stacked silicon die 202 and a substrate 204. The die 202 can include a power subsystem. A back side 206 of the die 202 can be exposed to a probe 208 during a BBI attack in which a resistance of the bulk silicon of the die 202 forms an RC circuit with elements of the power subsystem when the probe 208 injects one or more voltage pulses. Formation of this RC circuit can cause abnormal behavior of the power subsystem and potentially cause abnormal behavior of a security asset of the die 202, such as a root of trust. For example, an electromagnetic fault injection (EMFI) attack on the package can be converted to a voltage attack on a transistor through the RC circuit.

FIG. 3 illustrates example systems on chip (SoC) 300, 330, and 360. For example, SoC 300 represents a monolithic SoC that includes a die 302 mounted on a package substrate 304. The monolithic SoC 300 is not vulnerable to fault injection attacks for numerous reasons. For example, the die logic of SoC 300 is deeply embedded in several metal layers and thus is not exposed by chip decapsulation. Additionally, the bus interconnect is not exposed and is typically optimized in a sea of gates distributed across the SoC 300. Global and/or local EMFI attacks on SoC 300 are challenging to perform on the interconnect due to the position of the logic being unknown, and the same is true for other types of fault injection attacks. Micro-probing the internal logic requires knowledge of the exact position of the logic and is relatively expensive even after decapsulation.

In contrast to SoC 300, SoCs 330 and 360 are more vulnerable to fault injection attacks. For example, SoC 330 represents a standard package that includes two or more stacked silicon dies 332 and 334 mounted on a package substrate 336. Similarly, SoC 360 represents an advanced package that includes two or more stacked silicon dies 362 and 364 mounted on an interposer 366 that is mounted on a package substrate 368. SoC 330 and SoC 360 have die to die interconnects 338 and 370 that are fully exposed. For example, die to die interconnects can be exposed without decapsulation because voltage glitch EMFI can be performed as a non-invasive attack directly on the package. As a result of this exposure, global and/or local EMFI attacks on SoC 330 and SoC 360 are less challenging because the position of the die to die interconnect is readily apparent, and the same is true for other types of fault injection attacks. This die to die interconnect is a security asset that can benefit from protection.

FIG. 4 illustrates example wafer level fanout packages 400 and 450. For example, package 400 represents a typical wafer level fanout package having a backside 402 exposed by removal of a heat sink. As a result of this exposure, locations of security assets, such as a root of trust location 404 and a die to die interconnect location 406, can be easily determined and fault injection attacks can be successfully performed. In contrast to package 400, package 450 represents a wafer level fanout package with hybrid shielding. For example, an oxide layer 452 can be provided on a back side of the dies of the package 450. This oxide layer 452 can be used to permanently attach selective glass carriers 454 and 456 to the backside of package 450 at a root of trust location and a die to die interconnect location of package 450. A remainder of the backside area of package 450 can be left exposed for attachment of a heat sink. In this way, the selective glass carriers 454 and 456 and oxide layer 452 can provide electrical insulation that protects the root of trust location and the die to die interconnect location from fault injection attacks while also providing sufficient thermal conductivity for applications that require a heat sink.

FIG. 5 is a block diagram illustrating example selective glass carriers 500. In one example, a width of a selective glass carrier 502 can extend beyond a security asset location 504 to an extent sufficient to reduce a success rate of fault injection attacks from a side of the security asset. The amount by which the selective glass carrier 502 extends beyond the security asset location 504 can be determined based on results from experimental fault injection attacks on test packages using various types of fault injection attacks. Thus, an exact beach front for the selective glass carrier can be refined for a desired protection profile.

Compared to an SoC 506 without hybrid shielding, an SoC 508 with hybrid shielding can prevent fault injection attacks by using an oxide layer 510 to attach a selective glass carrier 512 on a backside of a stacked silicon die 514 only on top of security assets, such as a root of trust 516. By stacking a silicon carrier 518 with oxide fusion bonding, an additional oxide layer 520 can be introduced between the active silicon and the silicon carrier 518. A bonding silicon layer 522 can be provided on the oxide layer 510 in an area of the stacked silicon die 514 in which the selective glass carrier 512 is not permanently attached. The silicon carrier 518 can thus be attached to the selective glass carrier 512 and the bonding silicon layer 522 by the additional oxide layer 520.

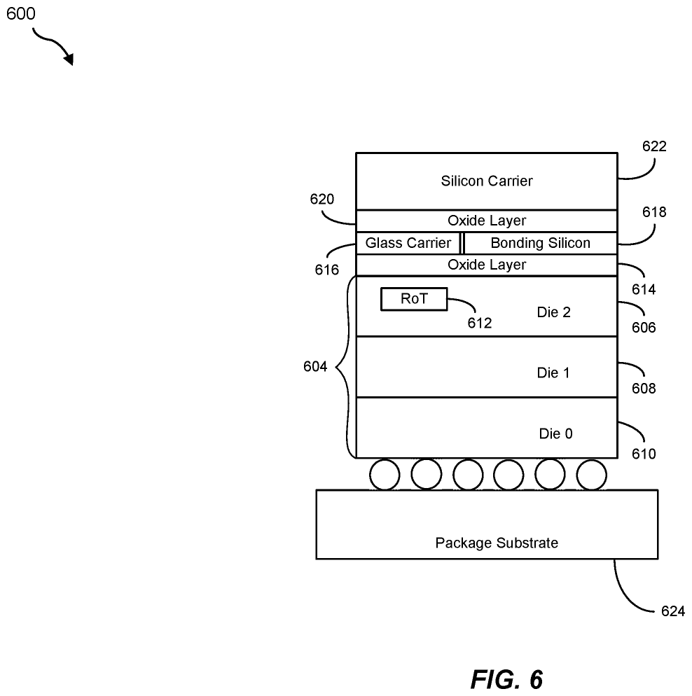

FIG. 6 illustrates example 3D stacked integrated circuit package 600. For example, a stacked silicon die 604 can include multiple stacked silicon dies stacked atop one another, such as top silicon die 606, middle silicon die 608, and bottom silicon die 610. A security asset 612, such as a root of trust, can be located in any or all of the silicon dies 606-610. Oxide layer 614 can be provided atop a back side of the stacked silicon die 604, such as atop a back side of top silicon die 606. A selective glass carrier 616 can be permanently attached to the back side of stacked silicon die 604 by oxide layer 614 in a location above the security asset 612. A bonding silicon layer 618 can also be permanently attached to the back side of stacked silicon die 604 by oxide layer 614. An additional oxide layer 620 can be provided atop the selective glass carrier 616 and the bonding silicon layer 618. A silicon carrier 622 can be attached (e.g., permanently) atop the selective glass carrier 616 and the bonding silicon layer 618 by the additional oxide layer 620. A front side of stacked silicon die 604 can be attached to a package substrate 624 using, for example, bumps and/or microbumps. In this way, selective glass carrier 616 can provide electrical insulation that prevents back side fault injection attacks on security asset 612.

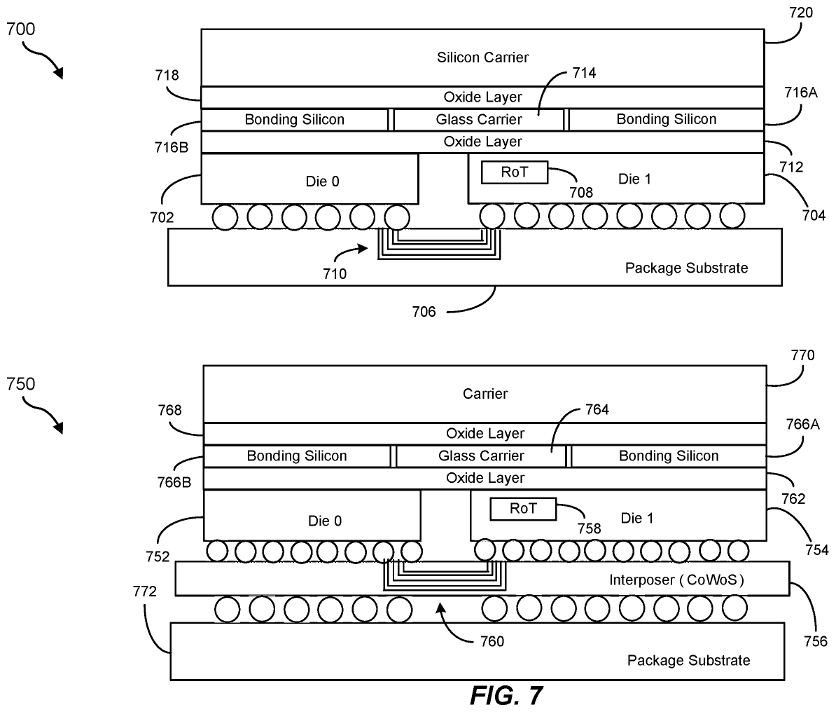

FIG. 7 is a block diagram illustrating example 2.5D stacked integrated circuit packages 700 and 750. For example, a stacked silicon die can correspond to two or more silicon dies 702 and 704 stacked in a 2.5D configuration on a package substrate 706. Any or all of stacked silicon dies 702 and 704 can correspond to single dies, multiple dies stacked in a 3D manner, and/or combination thereof. A security asset 708, such as a root of trust, can be located in any or all of the silicon dies 702 and 704. Alternatively or additionally, a security asset 710, such as a die to die interconnect, can be located in the package substrate 706. Oxide layer 712 can be provided atop a back side of the stacked silicon die, such as atop back sides of silicon dies 702 and 704. A selective glass carrier 714 can be permanently attached to the back side of the stacked silicon die by oxide layer 712 in a location above one or more of the security assets 708 and/or 710. A bonding silicon layer 716A and 716B can also be permanently attached to the back side of the stacked silicon die by oxide layer 712. An additional oxide layer 718 can be provided atop the selective glass carrier 714 and the bonding silicon layer 716A and 716B. A silicon carrier 720 can be attached (e.g., permanently) atop the selective glass carrier 714 and the bonding silicon layer 716A and 716B by the additional oxide layer 718. A front side of stacked silicon die can be attached to the package substrate 706 using, for example, bumps and/or microbumps. In this way, selective glass carrier 714 can provide electrical insulation that prevents back side fault injection attacks on one or more security assets 708 and/or 710.

Example 2.5D stacked integrated circuit package 750 demonstrates a stacked silicon die that can correspond to two or more silicon dies 752 and 754 stacked in a 2.5D configuration on an interposer 756. Any or all of stacked silicon dies 752 and 754 can correspond to single dies, multiple dies stacked in a 3D manner, and/or combination thereof. A security asset 758, such as a root of trust, can be located in any or all of the silicon dies 752 and 754. Alternatively or additionally, a security asset 760, such as a die to die interconnect, can be located in the interposer 756. Oxide layer 762 can be provided atop a back side of the stacked silicon die, such as atop back sides of silicon dies 752 and 754. A selective glass carrier 764 can be permanently attached to the back side of the stacked silicon die by oxide layer 762 in a location above one or more of the security assets 758 and/or 760. A bonding silicon layer 766A and 766B can also be permanently attached to the back side of the stacked silicon die by oxide layer 762. An additional oxide layer 768 can be provided atop the selective glass carrier 764 and the bonding silicon layer 766A and 766B. A silicon carrier 770 can be attached (e.g., permanently) atop the selective glass carrier 764 and the bonding silicon layer 766A and 766B by the additional oxide layer 768. Interposer 756 can be attached to a package substrate 772 using, for example, bumps and/or microbumps. In this way, selective glass carrier 764 can provide electrical insulation that prevents back side fault injection attacks on one or more security assets 758 and/or 760.

As set forth above, the systems and methods disclosed herein can prevent fault injection attacks. For example, by adding an oxide layer (e.g., thickness 1-2 um) on a back side of a stacked silicon die (e.g., between transistors and bulk silicon), voltage glitches can be restricted from reaching a power subsystem of a stacked silicon die package. The oxide layer can function as an electrical insulator that acts as a barrier to injected voltage pulses, thus preventing a low-cost fault injection attack on the package and one or more security assets (e.g., on a root of trust (ROT) and/or die to die interconnect) of the stacked silicon die. In some implementations, the oxide layer can permanently attach a selective glass carrier on the back side of the package. The glass carrier can also function as an electrical insulator that acts as a barrier to injected voltage pulses, thus further preventing the low-cost fault injection attacks on the package. In some of these implementations, the oxide layer can permanently attach one or more the selective glass carriers on the back side of the package in one or more locations of one or more security assets. The rest of the backside of the stacked silicon die can be exposed to allow mounting of a heat sink to address thermal issues by providing a thermal path while the oxide layer and glass carrier provide electrical insulation for the one or more security assets. Benefits include a low cost way to prevent fault injection attacks for performance applications that experience thermal issues.

While the foregoing disclosure sets forth various implementations using specific block diagrams, flowcharts, and examples, each block diagram component, flowchart step, operation, and/or component described and/or illustrated herein can be implemented, individually and/or collectively, using a wide range of hardware, software, or firmware (or any combination thereof) configurations. In addition, any disclosure of components contained within other components should be considered example in nature since many other architectures can be implemented to achieve the same functionality.

The process parameters and sequence of steps described and/or illustrated herein are given by way of example only and can be varied as desired. For example, while the steps illustrated and/or described herein can be shown or discussed in a particular order, these steps do not necessarily need to be performed in the order illustrated or discussed. The various example methods described and/or illustrated herein can also omit one or more of the steps described or illustrated herein or include additional steps in addition to those disclosed.

While various implementations have been described and/or illustrated herein in the context of fully functional computing systems, one or more of these example implementations can be distributed as a program product in a variety of forms, regardless of the particular type of computer-readable media used to actually carry out the distribution. The implementations disclosed herein can also be implemented using modules that perform certain tasks. These modules can include script, batch, or other executable files that can be stored on a computer-readable storage medium or in a computing system. In some implementations, these modules can configure a computing system to perform one or more of the example implementations disclosed herein.

The preceding description has been provided to enable others skilled in the art to best utilize various aspects of the example implementations disclosed herein. This example description is not intended to be exhaustive or to be limited to any precise form disclosed. Many modifications and variations are possible without departing from the spirit and scope of the present disclosure. The implementations disclosed herein should be considered in all respects illustrative and not restrictive. Reference should be made to the appended claims and their equivalents in determining the scope of the present disclosure.

Unless otherwise noted, the terms “connected to” and “coupled to” (and their derivatives), as used in the specification and claims, are to be construed as permitting both direct and indirect (i.e., via other elements or components) connection. In addition, the terms “a” or “an,” as used in the specification and claims, are to be construed as meaning “at least one of.” Finally, for ease of use, the terms “including” and “having” (and their derivatives), as used in the specification and claims, are interchangeable with and have the same meaning as the word “comprising.”

What is claimed is:

1. An integrated circuit, comprising:
a stacked silicon die;
an oxide layer provided on a back side of the stacked silicon die; and
a selective glass carrier permanently attached to the oxide layer in a position that restricts voltage glitches from reaching a power subsystem of the stacked silicon die.

2. The integrated circuit of claim 1, wherein the oxide layer permanently attaches the selective glass carrier on the back side of the stacked silicon die in a location of a security asset of the stacked silicon die.

3. The integrated circuit of claim 2, wherein the security asset corresponds to a root of trust of the stacked silicon die.

4. The integrated circuit of claim 2, wherein the security asset corresponds to a die to die interconnect of the stacked silicon die.

5. The integrated circuit of claim 2, wherein the selective glass carrier extends beyond the location of the security asset to an extent sufficient to reduce a success rate of fault injection attacks from a side of the security asset.

6. The integrated circuit of claim 1, wherein the selective glass carrier is not positioned in an area of the stacked silicon die that does not contain a security asset.

7. An integrated circuit package, comprising:
an integrated circuit that includes:
a stacked silicon die;
an oxide layer on a back side of the stacked silicon die; and
a selective glass carrier permanently attached to the oxide layer in a position that restricts voltage glitches from reaching a power subsystem of the stacked silicon die;
a bonding silicon layer provided on the oxide layer in an area of the stacked silicon die in which the selective glass carrier is not permanently attached;
a silicon carrier attached to the selective glass carrier and the bonding silicon layer; and
a substrate attached to a front side of the stacked silicon die.

8. The integrated circuit package of claim 7, further comprising:
a heat sink attached to the silicon carrier.

9. The integrated circuit package of claim 7, further comprising:
an additional oxide layer attaching the silicon carrier to the selective glass carrier and the bonding silicon layer.

10. The integrated circuit package of claim 7, wherein the oxide layer permanently attaches the selective glass carrier on the back side of the stacked silicon die in a location of a security asset of the stacked silicon die.

11. The integrated circuit package of claim 10, wherein the security asset corresponds to a root of trust of the stacked silicon die.

12. The integrated circuit package of claim 10, wherein the security asset corresponds to a die to die interconnect of the stacked silicon die.

13. The integrated circuit package of claim 10, wherein the selective glass carrier extends beyond the location of the security asset to an extent sufficient to reduce a success rate of fault injection attacks from a side of the security asset.

14. The integrated circuit package of claim 7, wherein the selective glass carrier is not positioned in an area of the stacked silicon die that does not contain a security asset.

15. The integrated circuit package of claim 7, wherein the stacked silicon die includes two or more 3D stacked silicon dies.

16. The integrated circuit package of claim 7, wherein the stacked silicon die includes multiple silicon dies stacked on an interposer.

17. A method comprising:
providing a stacked silicon die;
providing an oxide layer on a back side of the stacked silicon die; and
permanently attaching a selective glass carrier to the oxide layer in a position that restricts voltage glitches from reaching a power subsystem of the stacked silicon die.

18. The method of claim 17, wherein the oxide layer permanently attaches the selective glass carrier on the back side of the stacked silicon die in a location of a security asset of the stacked silicon die.

19. The method of claim 18, wherein the security asset corresponds to at least one of a root of trust of the stacked silicon die or a die to die interconnect of the stacked silicon die.

20. The method of claim 18, wherein the selective glass carrier extends beyond the location of the security asset to an extent sufficient to reduce a success rate of fault injection attacks from a side of the security asset.
